(19) United States
(12) Patent Application Publication
(10) Pub. No.: US 2009/0250737 A1
(43) Pub. Date: Oct. 8, 2009

(54) SECURE MEMORY DEVICE OF THE ONE-TIME PROGRAMMABLE TYPE

(75) Inventors: Philippe Candelier, Saint Mury (FR); Philippe Gendrier, Grenoble (FR); Joel Damiens, La Motte Servolex (FR); Elise Le Roux, Grenoble (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMicroelectronics S.A., Montrouge (FR)

(21) Appl. No.: 12/419,921

(22) Filed: Apr. 7, 2009

(30) Foreign Application Priority Data
Apr. 8, 2008 (FR) 08 52353

(51) Int. Cl. H01L 29/94; H01L 29/00

(52) U.S. Cl. 257/296; 257/379; 257/E29.001; 257/E29.345

(57) ABSTRACT

The integrated circuit includes a memory device of the irreversibly electrically programmable type. This device includes several memory cells, each memory cell having a dielectric zone positioned between a first electrode and a second electrode. Each memory cell is further associated with an access transistor. At least one first electrically conductive link electrically couples to the first electrodes of at least two memory cells, these first two electrodes being coupled to one and the same bias voltage. The first electrically conductive link is positioned in substantially a same plane as the first electrodes of the two memory cells.

### PRIORITY CLAIM

The present application claims priority from French Application for Patent No. 08 52353 filed Apr. 8, 2008, the disclosure of which is hereby incorporated by reference.

### BACKGROUND OF THE INVENTION

1. Technical Field of the Invention

The present invention relates to integrated circuits, and in particular memory integrated devices of the “one-time programmable” type, also known to those skilled in the art by the acronym “OTP”.

2. Description of Related Art

An OTP memory is well known to those skilled in the art. It comprises fusible elements, such as capacitors, that become electrically “blown”, that is, the dielectric of the capacitor becomes irreversibly electrically damaged, so that the latter then behaves as a low-value resistor.

It is possible, using integrated circuit attacks of the chemical type for example, to be able to recover the electrodes of the capacitors and then, by physical analysis techniques, for example of the electron microscopy type, to be able to detect the surface potential of the electrodes and so determine which capacitors have been “blown”. This thus gives access to the state of programming of the memory.

There is a need in the art to protect OTP memory devices from such attacks and the discovery of the state of programming of the memory.

### SUMMARY OF THE INVENTION

According to one embodiment, a memory device of the “OTP” type is proposed that makes it very difficult, or even almost impossible, to determine the programming of these memory devices by physical analysis systems.

According to one aspect, there is thus proposed an integrated circuit comprising a memory device of the irreversibly electrically programmable type comprising several memory cells, each memory cell comprising a dielectric zone positioned between a first electrode and a second electrode electrically coupled to a transistor.

According to a general characteristic of this aspect, the memory device also comprises at least one first electrically conductive link means, electrically coupled to the first electrodes of at least two memory cells, these first electrodes being designed to be coupled to one and the same bias voltage, for example by means of a plating positioned on the integrated circuit situated above the plane of the first electrodes, and the first link means is positioned substantially in the same plane as the first electrodes of these two memory cells.

Thus, it makes it possible to render the first two electrodes of the two memory cells equipotential. Because of this, even if, by chemical attack, the plating that links the two memory cells is destroyed, it is not possible to render these two memory cells electrically independent because of the presence of the first link means situated in the same plane as the first electrodes of these two memory cells. Because of this, it is extremely difficult, even almost impossible, to detect, by a physical analysis means, of the electron microscopy type for example, a difference of surface potential between the first two electrodes, and consequently determine whether the corresponding dielectric zones have or have not been electrically blown.

Because of the short-circuiting of the first electrodes of the two dielectric zones of the two memory cells, the semiconductor chambers positioned in the substrate, and serving, for each memory cell, as second electrode and drain of the access transistor, are not at the same potential when one of the dielectric zones is electrically blown and the other is not. Consequently, because of the capacitive coupling that exists between the drain and the gate of the transistor of each memory cell, the gate of the transistor can present a different surface potential depending on whether the dielectric zone associated with this transistor has or has not been electrically blown.

The perception of these surface potential differences on the gates of the transistors is, however, more difficult. That said, in order to minimize this risk, it is preferable for the memory device to also comprise a second electrically conductive link means, electrically coupled to the control electrodes of the transistors of two memory cells, and positioned substantially in the same plane as the control electrodes of these two memory cells, these two control electrodes naturally being designed to be coupled to one and the same control voltage.

Although the invention applies to any type of memory architecture of the “irreversibly electrically programmable” type, for example those providing switches connected to the bias voltage, and in particular having an architecture of the type of that described in the French Application for Patent No. 08 52354 filed Apr. 8, 2008 and entitled “Method of Programming a Memory Device of the One-time Programmable Type and Integrated Circuit Incorporating Such a Memory Device”, the disclosure of which is incorporated by reference, it applies particularly advantageously to an architecture with bias voltage shared by all the dielectric or capacitive zones, which makes it possible to have massive parallel interconnections between the different capacitors and consequently makes it possible to multiply the number of first link means, which makes it all the more difficult to detect the programming of the memory plane by a physical analysis, in particular an analysis by potential contrast.

According to an embodiment, a memory device comprises a memory plane comprising first sets of memory cells, for example rows of memory cells, extending in a first direction, and second sets of memory cells, for example columns of memory cells, extending in a second direction, the first electrodes of all the memory cells being designed to be coupled to the same bias voltage. The memory device further comprises several first link means respectively electrically coupled to the first electrodes of two adjacent memory cells of each first set, all the first link means being situated substantially in the same plane as said first electrodes.

Also, in another exemplary embodiment of architecture with shared bias voltage, each first link means is advantageously electrically coupled to the first electrodes of two pairs of memory cells belonging respectively to two first adjacent sets (rows, for example), and to two second adjacent sets (columns).

According to one embodiment, the memory device can also comprise several second link means respectively electrically coupled to the control electrodes of two adjacent memory cells of each first set, all the second link means being situated substantially in the same plane as said control electrodes.

In an embodiment, an integrated circuit comprises: a substrate of a first conductivity type; a first well of a second conductivity type defining a first plate of a first capacitor associated with a first memory cell; a second well of the second conductivity type defining a first plate of a second capacitor associated with a second memory cell; an isolation structure separating the first and second wells; an oxide layer overlying the first plates of the first and second capacitors; and a first electrically conductive link layer overlying the oxide layer and the isolation structure.

In an embodiment, an integrated circuit comprises: a memory device comprising first and second one time programmable memory cells, each one time programmable memory cell comprising an access transistor and a capacitor formed by a dielectric layer positioned between a first electrode and a second electrode. Each second electrode is formed in a substrate and the first electrode is formed above the substrate. The first electrodes of the first and second one time programmable memory cells are formed of a first electrically conductive link electrically connecting the first electrodes of first and second one time programmable memory cells, the first electrically conductive link overlying the dielectric layer and an isolation structure formed in the substrate separating the second electrodes.

### BRIEF DESCRIPTION OF THE DRAWINGS

Other advantages and characteristics of the invention will become apparent on examining the detailed description of modes of implementation and embodiments, wholly non-limiting, and the appended drawings in which:

FIG. 1 is an exemplary memory plane according to the invention;

FIG. 2 illustrates in more detail a portion of the layout diagram seen from above of the memory plane of FIG. 1;

FIG. 3 is a cross-sectional schematic view along the line III-III of FIG. 2; and

FIG. 4 schematically illustrates a portion of an exemplary memory plane according to the invention.

### DETAILED DESCRIPTION OF THE PREFERRED EMBODIMENTS

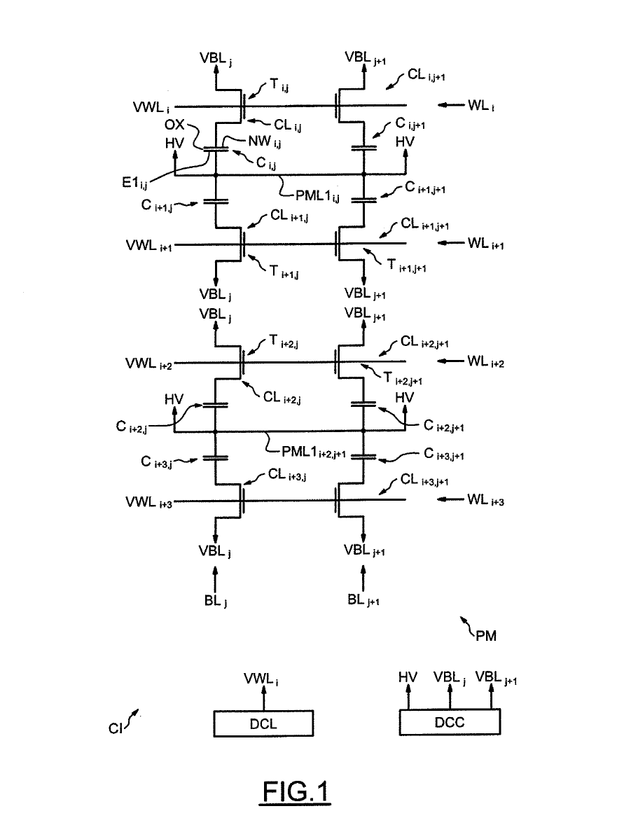

In FIG. 1, the reference PM designates a memory device of the “irreversible electrical programming” type or even of the “one-time programmable” type. This memory plane is implemented within an integrated circuit CI.

In FIG. 1, and in the interests of simplification, essentially only the actual memory plane of the memory is represented, which here, again in the interests of simplification, comprises eight memory cells organized in four rows WLᵢ, WLᵢ₊₁, WLᵢ₊₂, WLᵢ₊₃ and two columns BLⱼ and BLⱼ₊₁.

Each row of memory cells here forms a first set of memory cells which extends in a first direction, whereas each column of memory cells forms a second set of memory cells which extends in a second direction.

The rows WLᵢ-WLᵢ₊₃ form lines of words of the memory, whereas the columns BLⱼ and BLⱼ₊₁ form lines of bits of the memory.

Of course, this memory plane has an associated row decoder DCL and an associated column decoder DCC of conventional structure known per se.

Each cell, for example the memory cell CL_{i,j}, of the memory plane comprises a fusible dielectric zone C_{i,j} here comprising a capacitor having a dielectric flanked by two electrodes, and a transistor T_{i,j} which can be a bipolar transistor or even an MOS transistor.

In the example described here, the MOS transistor of each memory cell is a transistor of the “field gradient” type (“drift transistor”, according to the term well known to those skilled in the art).

Each transistor is controlled on its control electrode (gate) by the corresponding line of words.

Moreover, each dielectric zone (capacitor) C_{i,j} comprises a first electrode E1_{i,j}, designed to be connected to a bias voltage HV, and a second electrode NW_{i,j}, formed in this example as will be seen hereinbelow by a semiconductor chamber, and connected to the drain of the corresponding transistor T_{i,j}.

Moreover, the source of the transistors T_{i,j} of a column “j” is connected to a voltage VBLⱼ. Finally, the control electrodes of the transistors of a row “i” are controlled by a control voltage VWLᵢ.

In programming mode, the bias voltage HV is equal to a programming voltage, for example a high programming voltage of the order of 7 volts.

Moreover, to select a cell (for example the cell CL_{i,j}) that is to be programmed, that is, for which there is the desire to electrically blow the dielectric OX of the capacitor, a voltage VWLᵢ, equal, for example, to 2.5 volts, is applied to the corresponding row WL, and a zero voltage is applied to the other lines of words.

At the same time, a voltage VBLⱼ, equal to zero, is applied to the column BLⱼ, whereas a voltage VBLⱼ₊₁ (for example) equal to 2.5 volts is applied to the other columns.

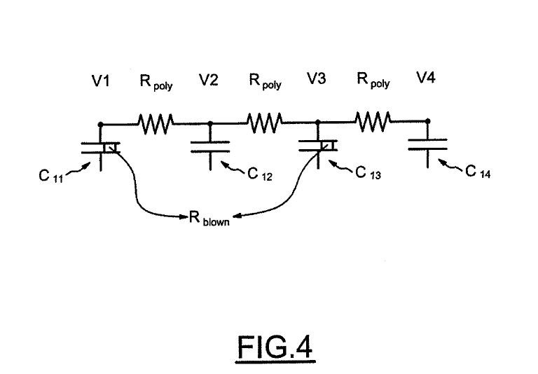

Because of this, only the transistor T_{i,j} of the memory cell CL_{i,j} is in the passing state, which electrically and irreversibly damages the dielectric OX of the capacitor C_{i,j}, by creating in this dielectric defects conferring on this dielectric a resistance of resistive value R_{blown} (FIG. 4).

It is then considered in this case that a logic “1” has been, for example, programmed in the memory cell.

In read mode on this cell CL_{i,j} for example, a voltage VWLᵢ, equal for example to 2.5 volts, is applied to the corresponding row WLᵢ, a zero voltage is applied to the other lines of words and the voltage HV is taken, for example, to be equal to a read voltage of the order of 2.5 volts, whereas the voltage VBLⱼ is this time equal to 0.5 volt for example. A current is then detected in the column BLⱼ, deriving from the cell CL_{i,j}.

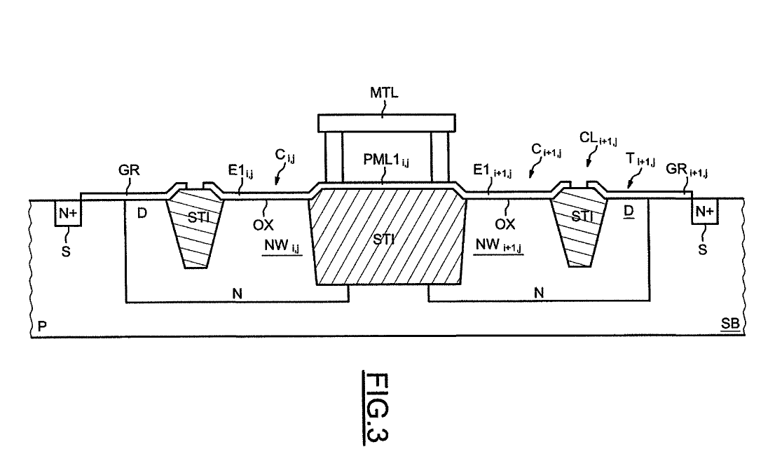

As illustrated in FIG. 3, platings MTL are provided, situated in the integrated circuit CI, with greater plating levels compared to the level of implementation of the electrodes of the capacitors, linking, for example, within one and the same column, the first electrodes of two capacitors of two adjacent memory cells, for example the first electrode E1_{i,j} of the capacitor C_{i,j} and the first electrode E1_{i+1,j} of the capacitor C_{i+1,j}. It is this plating MTL that will be biased at the voltage HV.

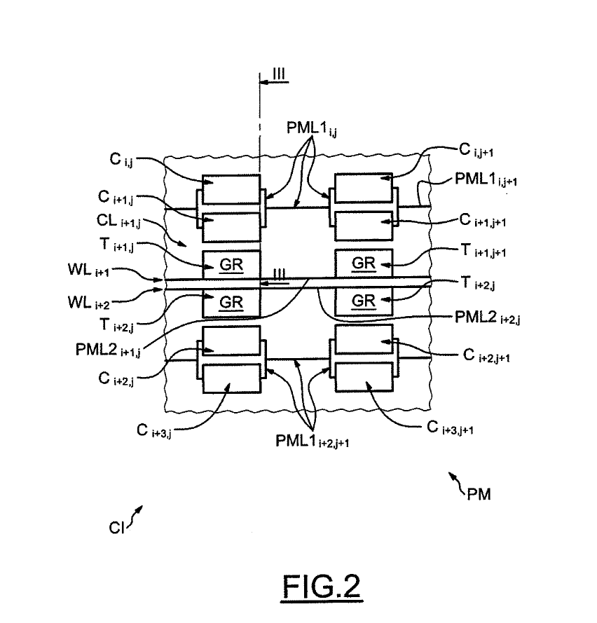

Moreover, as illustrated in particular in the partial layout diagram of the integrated circuit of FIG. 2 (in which the first electrodes of the capacitors and the gates of the transistors are represented seen from above), but also in FIG. 3, a first electrically conductive link means PML1_{i,j} links the first electrodes of the capacitors of two pairs of memory cells, namely a first pair of capacitors C_{i,j} and C_{i+1,j} of two memory cells situated on two adjacent rows and on one and the same column, and a second pair of capacitors C_{i,j+1} and C_{i+1,j+1} of the two memory cells respectively situated on the two adjacent rows and on the neighboring column.

Moreover, as illustrated in FIG. 3, this link means PML1_{i,j} is situated substantially in the same horizontal plane as all the first electrodes to which it is electrically coupled.

There is another first link means PML1_{i+2,j+1} linking the first electrodes of the capacitors C_{i+2,j+1}, C_{i+2,j}, C_{i+3,j}, C_{i+3,j+1}, of the memory cells respectively situated on the columns j and j+1 and on the rows i+2 and i+3.

The fact that these various first link means are situated substantially in the same horizontal plane as the first electrodes to which they are electrically coupled makes it much more difficult, even almost impossible, to read the programming of the memory plane by physical analysis techniques, for example of the “electron microscopy” type.

In practice, even if, by chemical attack or mechanical-chemical polishing, the platings MTL are destroyed to uncover the first electrodes and the first electrically conductive link means, all these elements are placed at the same potential, which makes it extremely difficult to detect dielectric zones that are electrically blown, and those that are not.

Although these first electrically conductive link means can be implemented by any electrically conductive material, it is particularly advantageous to use the same material as that used to form the first electrodes of the capacitors. In practice, not only does this make it possible to use one and the same material and one and the same production mask, but this makes a differential chemical attack aiming to eliminate the first link means while leaving the first electrodes intact almost impossible. Polysilicon will be used, for example, as the material.

Moreover, although the presence of such an electrically conductive link means between electrodes provides a significant improvement in resolving the problem of non-detectability of the surface potential of the electrodes of the capacitors, it is particularly advantageous for the geometry and the dimensions of each first link means PML1 to be chosen for the voltage difference V3−V2 (FIG. 4), between a first electrode of an electrically blown capacitor and a first electrode of a non-electrically blown capacitor to be less than the detection sensitivity of a surface potential analysis device, for example a device of the “secondary electron microscopy” (SEM) type.

In this respect, a resistive value will be chosen for the first link means that is advantageously well below the resistive value of a dielectric zone that has been electrically blown.

Thus, it is possible to choose a resistive value R_{poly} for the first link means such that R_{blown} is equal to k times R_{poly}, with k at least equal to a few units, for example 5, R_{blown} designating the resistive value of a dielectric zone that has been electrically blown.

As an example, a resistive value R_{poly} equal to a twentieth of the resistive value R_{blown} can be chosen.

In order to prevent the problem resolved on the first electrodes of the capacitors from being shifted to the gates of the associated transistors, that is being able, via the capacitive coupling between the gate and the drain of the transistor, to detect surface potential contrasts between the gates of the transistors associated with the blown dielectric zones and those associated with the non-blown dielectric zones, it is preferable, as illustrated in FIG. 2, to provide second electrically conductive link means PML2_{i+1,j} and PML2_{i+2,j} respectively electrically coupled to the control electrodes GR of the transistors of adjacent memory cells of each of the lines of words in the memory. Obviously, these second link means are also placed substantially in the same horizontal plane as the control electrodes of the corresponding transistors and preferably present a resistive value less than a few kilo-ohms. They are also advantageously made with the same material as that of the gate of the transistor which gives them a resistive value well below a few kilo-ohms.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. An integrated circuit, comprising:
a memory device of the irreversibly electrically programmable type comprising several memory cells, each memory cell comprising a dielectric zone positioned between a first electrode and a second electrode electrically coupled to a transistor; and
the memory device further comprising at least one first electrically conductive link, electrically coupling the first electrodes of at least two memory cells, the electrically coupled first electrodes coupled to receive one and the same bias voltage;
the first electrically conductive link being positioned in substantially a same plane as the first electrodes of the two memory cells.

2. The integrated circuit according to claim 1, wherein the first electrically conductive link is formed of a same material as that which is used to form the first electrodes of the memory cells.

3. The integrated circuit according to claim 1, in which a resistive value of the first electrically conductive link is equal to approximately 1/k times a resistive value of a dielectric zone electrically blown to irreversibly electrically program the memory cell, k being at least of the order of a few units.

4. The integrated circuit according to claim 1, wherein the memory device further comprises a second electrically conductive link, electrically coupling control electrodes of the transistors of said at least two memory cells, the second electrically conductive link being positioned in substantially a same plane as the control electrodes of the two memory cells, the control electrodes being coupled to one and the same control voltage.

5. The integrated circuit according to claim 4, wherein the second electrically conductive link means is formed of a same material as that which is used to form the control electrodes of the transistors.

6. The integrated circuit according to claim 1, wherein the memory device comprises a memory plane comprising first sets of memory cells extending in a first direction and second sets of memory cells extending in a second direction, the first electrodes of the memory cells being coupled to one and the same bias voltage, the first electrically conductive link comprising several first electrically conductive links each respectively electrically coupling the first electrodes of two adjacent memory cells of each first set, all first electrically conductive links being positioned in the same plane as said first electrodes.

7. The integrated circuit according to claim 6, wherein each first electrically conductive link is electrically coupled to the first electrodes of two pairs of memory cells belonging respectively to two first adjacent sets of memory cells and to two second adjacent sets of memory cells.

8. The integrated circuit according to claim 6, wherein the memory device further comprises a second electrically conductive link, electrically coupling control electrodes of the transistors of said at least two memory cells, the second electrically conductive link being positioned in substantially a same plane as the control electrodes of the two memory cells, the control electrodes being coupled to one and the same control voltage, the second electrically conductive link comprising several second electrically conductive links each respectively electrically coupling the control electrodes of two adjacent memory cells of each first set of memory cells, all the second electrically conductive links being positioned substantially in the same plane as said control electrodes.

9. An integrated circuit, comprising:
a substrate of a first conductivity type;
a first well of a second conductivity type defining a first plate of a first capacitor associated with a first memory cell;
a second well of the second conductivity type defining a first plate of a second capacitor associated with a second memory cell;
an isolation structure separating the first and second wells;
a dielectric layer overlying the first plates of the first and second capacitors; and
a first electrically conductive link layer overlying the oxide layer and the isolation structure.

10. The circuit of claim 9 wherein the first electrically conductive link layer is a polysilicon layer which overlies the dielectric layer and the isolation structure.

11. The circuit of claim 9 further including a metal layer vertically offset from, but in electrical connection with, the first electrically conductive link layer.

12. The circuit of claim 11 wherein the electrical connection between the vertically offset metal layer and the first electrically conductive link layer is made at a location over the isolation structure separating the first and second wells.

13. The circuit of claim 9 further comprising a first access transistor having a drain terminal formed in the first well and a second access transistor having a drain terminal formed in the second well.

14. The circuit of claim 13 wherein the first and second access transistors each have a source terminal formed in the substrate.

15. The circuit of claim 13 wherein the first and second access transistors each have a gate terminal formed in substantially a same plane as the first electrically conductive link layer, each gate terminal being formed of a second electrically conductive link layer which electrically interconnects at least two gate terminals of access transistors for adjacent memory cells.

16. An integrated circuit, comprising:
a memory device comprising first and second one time programmable memory cells, each one time programmable memory cell comprising an access transistor and a capacitor formed by a dielectric layer positioned between a first electrode and a second electrode; and
wherein each second electrode is formed in a substrate and the first electrode is formed above the substrate, the first electrodes of the first and second one time programmable memory cells being formed of a first electrically conductive link electrically connecting the first electrodes of first and second one time programmable memory cells, the first electrically conductive link overlying the dielectric layer and an isolation structure formed in the substrate separating the second electrodes.

17. The circuit of claim 16 wherein the first electrically conductive link layer is a polysilicon layer which overlies the dielectric layer and the isolation structure.

18. The circuit of claim 16 further including a metal layer vertically offset from, but in electrical connection with, the first electrically conductive link layer, the electrical connection between the vertically offset metal layer and the first electrically conductive link layer being made at a location over the isolation structure.

19. The circuit of claim 16 wherein each access transistor includes a gate terminal formed in substantially a same plane as the first electrically conductive link layer, each gate terminal being formed of a second electrically conductive link layer which electrically interconnects at least two gate terminals of access transistors for adjacent memory cells.

20. The circuit of claim 19 wherein the adjacent memory cells are adjacent to each other in a direction perpendicular to a direction with which the first and second one time programmable memory cells are adjacent.
